(19) United States
(12) Patent Application Publication
(10) Pub. No.: US 2021/0059083 A1
(43) Pub. Date: Feb. 25, 2021

(54) Foldable Electronic Device Display Enclosure

(71) Applicants: Nadia Ansari, Tustin, CA (US); Olivia Borland, Newport Beach, CA (US); Sabrina Do, Huntington Beach, CA (US); Catherine Herrick, Laguna Beach, CA (US); Zayna Lateef, Irvine, CA (US); Ariane Rednour, Newport Beach, CA (US)

(72) Inventors: Nadia Ansari, Tustin, CA (US); Olivia Borland, Newport Beach, CA (US); Sabrina Do, Huntington Beach, CA (US); Catherine Herrick, Laguna Beach, CA (US); Zayna Lateef, Irvine, CA (US); Ariane Rednour, Newport Beach, CA (US)

(21) Appl. No.: 16/995,201

(22) Filed: Aug. 17, 2020

Related U.S. Application Data
(63) Continuation of application No. 16/543,977, filed on Aug. 19, 2019, now abandoned.

(51) Int. Cl. H05K 9/00; A47B 23/00

(52) U.S. Cl. CPC H05K 9/0043; G06F 1/1613; A47B 23/002

(57) ABSTRACT

Foldable electronic device display enclosures that, when in use, enable users to block EMF radiation, particularly light, from being emitted beyond the electronic device holder are disclosed. A casing incorporates a cavity configured to accommodate an electronic device. The cavity is defined by a first wall, a second wall, a third wall, a fourth wall and a base. A cover is rotatably attached to an internal surface of the third wall, configured to be folded downwards and towards the cavity from an unfolded position and configured to be unfolded upwards and away from the cavity from a folded position. A first wing is hinged to a left portion of an internal surface of the cover. In the folded position, the first wing is positioned under the cover and within the cavity. A second wing is hinged to a right portion of the internal surface of the cover. In the folded position, the second wing is positioned under the cover and within the cavity.

### CROSS-REFERENCE

The present application is a continuation application of U.S. patent application Ser. No. 16/543,977, entitled “Foldable Electronic Device Display Enclosure” and filed on Aug. 19, 2019.

### FIELD

The present specification is related generally to the field of electronic device holders. More specifically, the present specification is related to various embodiments of a foldable electronic device display enclosure that, when in use, enables a user to block EMF radiation, particularly light, from being emitted beyond the electronic device holder.

### BACKGROUND

People now use electronic devices, such as, for example, laptops, smart phones and tablets, at all hours of the day and night. During use, these devices emit electric and magnetic field (EMF) radiation comprising extremely low frequency (ELF) waves, radio frequency (RF) waves, microwaves, and visible light. While the radiation emitted by these devices are non-ionizing, they can still adversely affect the health of individuals in proximity to the devices, even if those individuals are not actively using those devices.

In many situations, people who are not using an electronic device but are near a user of an electronic device are passively exposed to light. The light emitted from electronic devices may disturb those proximate the devices, hindering sleep or otherwise being an irritant. For example, when children occupy the same bedroom, college roommates have to live in the same dorm room or spouses are in their bedroom together, one person may choose to use his or her electronic device. While this may not be an issue during the day when it comes to exposure from visible light, at night, the visible light emanating from the device can be quite distracting and interrupt the sleep of the other person.

Furthermore, individuals like to use their electronic devices in conjunction with stands or mini-desks, which are often positioned on the user's lap and used to hold the device in place while the user is using or watching the device. Accordingly, any such electronic device holder must be compact and highly portable.

Conventional laptop stands fail to provide mechanisms for physically blocking the transmission of light from an electronic device screen to areas around the user. Privacy filters may be effective in blocking people from seeing what a person is doing on his or her screen, but they do not adequately stop the light itself from filling up a dark room. Moreover, these privacy filters tend to be hassle to repeatedly install and remove, which impairs usability. Conventional cubicles are, of course, quite large, not portable, and not able to be positioned on a user's lap.

Accordingly, there is need for an electronic device holder that can house an electronic device and when, in use, block EMF radiation, specifically light, from being emitted to areas proximate the electronic device. There is also need for the electronic device holder to be foldable to thereby be in a compact configuration when not in use.

### SUMMARY

The following embodiments and aspects thereof are described and illustrated in conjunction with systems, tools and methods, which are meant to be exemplary and illustrative, and not limiting in scope. The present application discloses numerous embodiments.

The present specification discloses an electronic device holder dimensioned to be positioned on a lap of a user comprising 1) a casing incorporating a cavity configured to accommodate an electronic device, wherein the cavity is defined by a first wall, a second wall, a third wall, a fourth wall and a base and wherein each of the first wall, the second wall, the third wall and the fourth wall have an internal surface facing the cavity, 2) a cover rotatably attached to the internal surface of the third wall, wherein the cover is configured to be folded downwards and towards the cavity from an unfolded position and configured to be unfolded upwards and away from the cavity from a folded position, 3) a first wing having a distal edge hinged to a left portion of an internal surface of the cover, wherein, in the folded position, the first wing is positioned under the cover and within the cavity, and 4) a second wing having a distal edge hinged to a right portion of the internal surface of the cover, wherein, in the folded position, the second wing is positioned under the cover and within the cavity.

Optionally, in the unfolded position, a plane of the cover lies substantially perpendicular to the base whereas in the folded position the plane of the cover lies substantially parallel to the base. In the unfolded position, an internal surface of the first wing is positioned at an angle relative to the internal surface of the cover and wherein the angle is greater than 90 degrees. In the unfolded position, an internal surface of the second wing is positioned at a second angle relative to the internal surface of the cover and wherein the second angle is greater than 90 degrees. In the folded position, an external surface of the cover is flush with a top surface of each of the first wall, the second wall, the third wall and the fourth wall.

Optionally, the casing has a substantially quadrilateral shape and wherein corners of the casing are rounded. The first wing comprises a first panel and a second panel and wherein the first panel and the second panel are rotatably connected to each other. The first panel is longer than the second panel of the first wing. The first wing is configured to be folded towards an internal surface of the cover such that the first panel of the first wing folds-in to touch the internal surface of the cover while the second panel of the first wing folds-in thereafter to touch the folded first panel.

Optionally, the first wing is configured to be unfolded away from the internal surface of the cover such that the second panel of the first wing unfolds followed by an unfolding of the first panel of the first wing. The second wing comprises a first panel and a second panel and wherein the first panel of the second wing and the second panel of the second wing are rotatably connected to each other. The first panel of the second wing is longer than the second panel of the second wing. The second wing is configured to be folded towards the internal surface of the cover such that the first panel of the second wing folds-in to touch the internal surface of the cover while the second panel of the second wing folds-in thereafter to touch the folded first panel of the second wing.

Optionally, the second wing is configured to be unfolded away from the internal surface of the cover such that the second panel of the second wing unfolds followed by an unfolding of the first panel of the second wing. The first wing and the second wing are hinged to proximal edges of the cover, wherein the first wing and the second wing are configured to lock at an angle relative to the internal surface of the cover when said cover is in the unfolded position, and wherein the angle is greater than 90 degrees.

Optionally, the electronic device holder further comprises a cushion, wherein a bottom surface of the casing is attached to the cushion.

The present specification also discloses a portable electronic device holder dimensioned to be positioned on a lap of a user, wherein a length and width of the portable electronic device holder is less than 24 inches, the portable electronic device holder comprising 1) a casing incorporating a cavity configured to accommodate an electronic device, wherein the cavity is defined by a first wall, a second wall, a third wall, a fourth wall and a base and wherein each of the first wall, the second wall, the third wall and the fourth wall have an internal surface facing the cavity, 2) a cover rotatably attached to the internal surface of the third wall, wherein the cover is configured to be folded downwards and towards the cavity from an unfolded position and configured to be unfolded upwards and away from the cavity from a folded position, 3) a first wing having a distal edge hinged to a left portion of an internal surface of the cover, wherein the first wing comprises a first panel and a second panel, wherein the first panel and the second panel are rotatably connected to each other, wherein, in the folded position, the first wing is positioned under the cover and within the cavity, wherein, in the unfolded position, an internal surface of the first wing is positioned at an angle relative to the internal surface of the cover and wherein the angle is greater than 90 degrees, and 4) a second wing having a distal edge hinged to a right portion of the internal surface of the cover, wherein the second wing comprises a first panel and a second panel, wherein the first panel of the second wing and the second panel of the second wing are rotatably connected to each other, wherein, in the folded position, the second wing is positioned under the cover and within the cavity, wherein, in the unfolded position, an internal surface of the second wing is positioned at a second angle relative to the internal surface of the cover, and wherein the second angle is greater than 90 degrees.

Optionally, in the unfolded position, a plane of the cover lies substantially perpendicular to the base whereas in the folded position the plane of the cover lies substantially parallel to the base. In the folded position, an external surface of the cover is flush with a top surface of each of the first wall, the second wall, the third wall and the fourth wall. The first wing is configured to be folded towards an internal surface of the cover such that the first panel of the first wing folds-in to touch the internal surface of the cover while the second panel of the first wing folds-in thereafter to touch the folded first panel and wherein the second wing is configured to be folded towards the internal surface of the cover such that the first panel of the second wing folds-in to touch the internal surface of the cover while the second panel of the second wing folds-in thereafter to touch the folded first panel of the second wing.

The present specification also discloses an electronic device holder comprising 1) a casing incorporating a cavity to accommodate the electronic device, said cavity being defined by first, second, third and fourth walls and a base, wherein each of the first, second, third and fourth sides respectively have first, second, third and fourth internal surfaces facing the cavity, 2) a cover hinged at an edge to the third internal surface, wherein the cover can be folded downwards and towards the cavity from an unfolded position and can be unfolded upwards and away from the cavity from a folded position, 3) a first wing having a distal edge hinged to a left portion of an internal surface of the cover, wherein the first wing has first, second and third panels hinged to each other, and 4) a second wing having a distal edge hinged to a right portion of the internal surface of the cover, wherein the second wing has first, second and third panels hinged to each other.

Optionally, in the unfolded position a plane of the cover lies substantially perpendicular to the base whereas in the folded position the plane of the cover lies substantially parallel to the base. When the holder is fully unfolded, the first and second wings extend beyond the cavity and respectively make angles greater than 90 degrees relative to the cover. In the folded position a top surface of the cover is flush with top surfaces of the respective first, second, third and fourth sides. The casing has a substantially quadrilateral shape, and wherein corners of the casing are rounded. The first panels of the respective first and second wings are shorter than the second and third panels of the respective first and second wings. The first wing can be folded towards an internal surface of the cover such that the first panel of the first wing folds-in to touch the internal surface of the cover, the second panel of the first wing folds-in thereafter to touch the folded first panel and finally the third panel of the first wing folds-in to touch the folded second panel, and wherein the second wing can be folded towards the internal surface of the cover such that the first panel of the second wing folds-in to touch the internal surface of the cover, the second panel of the second wing folds-in thereafter to touch the folded first panel of the second wing and finally the third panel of the second wing folds-in to touch the folded second panel. The first wing can be unfolded away from the internal surface of the cover such that the third panel of the first wing unfolds first followed by unfolding of the second panel of the first wing and thereafter unfolding of the first panel of the first wing, and wherein the second wing can be unfolded away from the internal surface of the cover such that the third panel of the second wing unfolds first followed by unfolding of the second panel of the second wing and thereafter unfolding of the first panel of the second wing. A wing is hinged to a proximal edge of the cover, said wing being configured to lock in an inclined position with reference to the cover when said cover is in the unfolded position.

The aforementioned and other embodiments of the present shall be described in greater depth in the drawings and detailed description provided below.

### BRIEF DESCRIPTION OF THE DRAWINGS

These and other features and advantages of the present specification will be further appreciated, as they become better understood by reference to the following detailed description when considered in connection with the accompanying drawings:

FIG. 1A shows a top view of an electronic device holder in a closed configuration, in accordance with some embodiments of the present specification;

FIG. 1B shows a top view of the electronic device holder of FIG. 1A in a partially opened configuration, in accordance with some embodiments of the present specification;

FIG. 1C shows a top view of the electronic device holder of FIG. 1A in a fully opened configuration, in accordance with some embodiments of the present specification;

FIG. 1D shows a perspective view of the electronic device holder of FIG. 1A in a fully opened configuration, in accordance with some embodiments of the present specification;

FIG. 2A shows a top view of another electronic device holder in a closed configuration, in accordance with some embodiments of the present specification;

FIG. 2B shows a top view of the electronic device holder of FIG. 2A in a partially opened configuration, in accordance with some embodiments of the present specification;

FIG. 2C shows a top view of the electronic device holder of FIG. 2A in a fully opened configuration, in accordance with some embodiments of the present specification;

FIG. 2D shows a side view of the electronic device holder of FIG. 2A in a fully opened configuration, in accordance with some embodiments of the present specification;

FIG. 3A shows a top view of yet another electronic device holder in a closed configuration, in accordance with some embodiments of the present specification; and

FIG. 3B shows a perspective view of the electronic device holder of FIG. 3A in a fully opened configuration, in accordance with some embodiments of the present specification.

### DETAILED DESCRIPTION

The term ‘EMF radiation’ refers to electric and magnetic field radiation that is non-ionizing in nature. In embodiments, the EMF radiation comprises extremely low frequency (ELF), radio frequency (RF), microwaves, WIFI signals, Bluetooth signals and visible light.

The term ‘electronic device’ refers to computing devices that are a source of EMF radiation. Such devices comprise, for example, laptops, mobile phones, and tablet computers.

The present specification is directed towards multiple embodiments. The following disclosure is provided in order to enable a person having ordinary skill in the art to practice the invention. Language used in this specification should not be interpreted as a general disavowal of any one specific embodiment or used to limit the claims beyond the meaning of the terms used therein. The general principles defined herein may be applied to other embodiments and applications without departing from the spirit and scope of the invention. Also, the terminology and phraseology used is for the purpose of describing exemplary embodiments and should not be considered limiting. Thus, the present invention is to be accorded the widest scope encompassing numerous alternatives, modifications and equivalents consistent with the principles and features disclosed. For purpose of clarity, details relating to technical material that is known in the technical fields related to the invention have not been described in detail so as not to unnecessarily obscure the present invention.

In the description and claims of the application, each of the words “comprise” “include” and “have”, and forms thereof, are not necessarily limited to members in a list with which the words may be associated. It should be noted herein that any feature or component described in association with a specific embodiment may be used and implemented with any other embodiment unless clearly indicated otherwise.

As used herein, the indefinite articles “a” and “an” mean “at least one” or “one or more” unless the context clearly dictates otherwise.

### First Embodiment

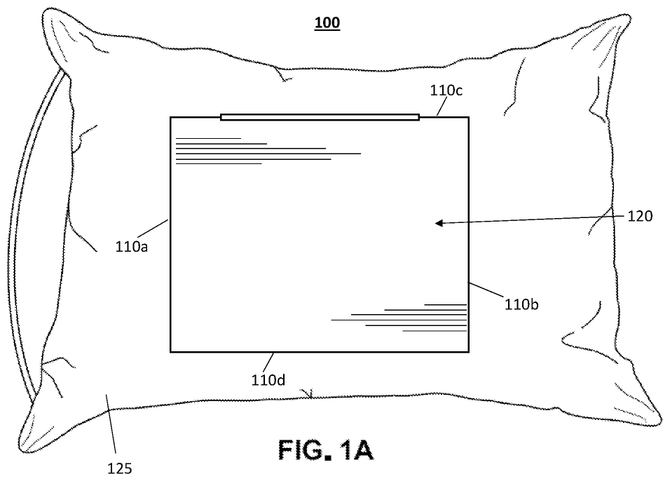

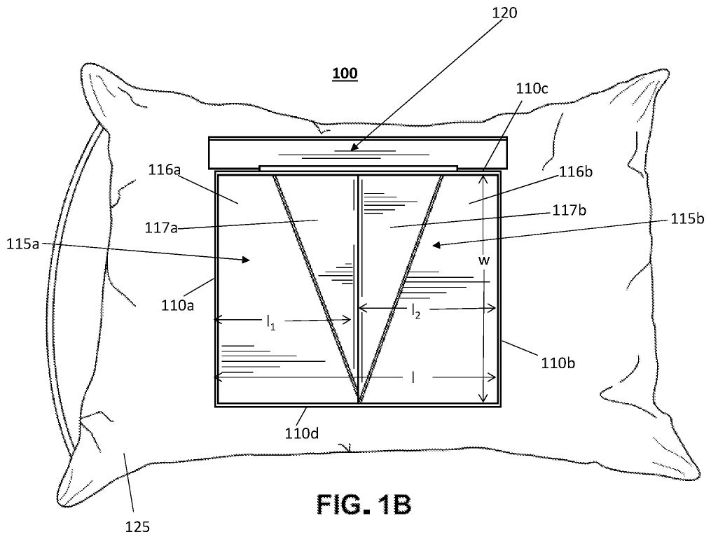

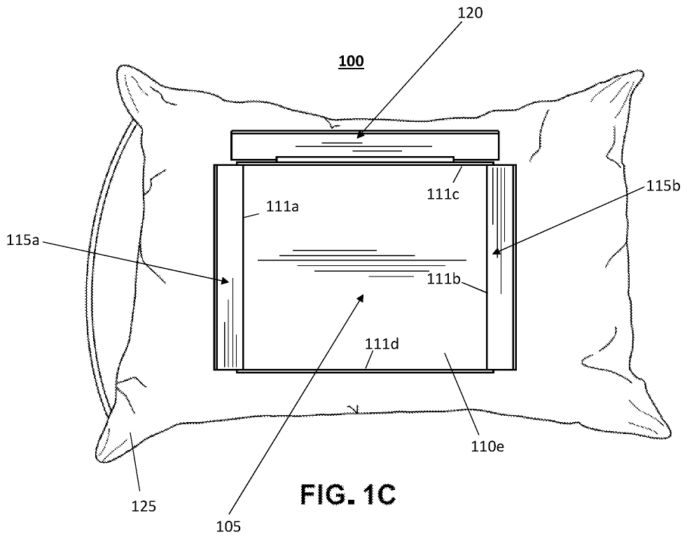

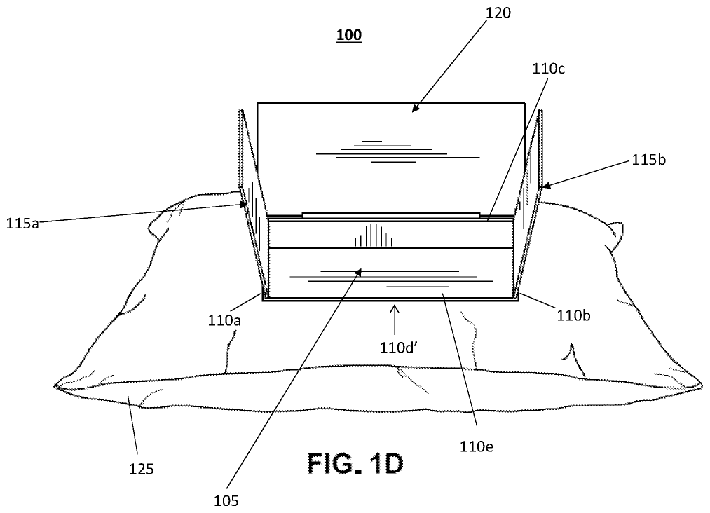

FIG. 1A shows a top view of an electronic device holder 100 in a closed configuration, FIG. 1B shows a top view of the electronic device holder 100 in a partially opened configuration, FIG. 1C shows a top view of the electronic device holder 100 in a fully opened configuration while FIG. 1D shows a perspective view of the electronic device holder 100 in a fully opened configuration, in accordance with some embodiments of the present specification. Referring now to FIGS. 1A, 1B, 1C and 1D simultaneously, the holder 100 comprises a cavity 105 defined by first, second, third and fourth sides 110a, 110b, 110c and 110d and a base 110e. In some embodiments, as shown in FIG. 1D, the cavity 105 is defined by the first, second, and third sides 110a, 110b, 110c and a base 110e (in other words, there is no need for the fourth side 110d). In various embodiments, the holder 100 is configured to be conveniently positioned on a user's lap. In some embodiments, the holder 100 is removably embedded into a support 125 of soft and pliable material, such as a cushion, that acts as a cushion between the holder 100 and the user's lap. It should be appreciated that the length and width of the electronic device holder 100 is preferably sized to allow for being comfortably positioned on a user's lap. Accordingly, the length and width of the electronic device holder 100 is preferably less than 24 inches long and less than 24 inches wide.

When the holder 100 is positioned on a horizontal plane, the first and second sides 110a, 110b form left and right vertical sides, the third and (optional) fourth sides 110c, 110d form upper and lower horizontal sides while the base 110e forms a bottom surface lying in the horizontal plane. The first, second, third and (optional) fourth sides 110a, 110b, 110c and 110d respectively have internal surfaces (facing inwards into the cavity 105) 111a, 111b, 111c and 111d (shown in FIG. 1C).

To use the device 100, the top cover 120 is first lifted up by holding a portion of the cover proximate the fourth side 110d, typically through a groove or small protrusion. Preferably, in a closed position, the top cover 120 is flush with one or more of the sides 110a, 110b, 110c, and 110d. The top cover 120 is hinged, connected, or otherwise rotatably attached to the third side 110c. Upon lifting the top cover 120, the edge of the top cover 120 proximate the fourth side 110d lifts vertically and is positioned above the device 100 such that the top cover 120 is now substantially perpendicular to the base 110e or cavity 105. FIG. 1B shows the top cover 120 lifted vertically and exposing components, such as a first wing 115a and a second wing 115b, positioned below the top cover 120 and inside the cavity 105. The first wing 115a and second wing 115b are in a folded configuration when the top cover 120 is first opened.

The first wing 115a (also referred to as a ‘left wing’) is hinged to the internal surface 111a of the first side 110a (also referred to as the ‘left side’) and the second wing 115b (also referred to as a ‘right wing’) is hinged to the internal surface 111b of the second side 110b (also referred to as the ‘right side’), much like how the edge of the top cover 120 (the edge lying proximate the third side 110c) is hinged to the internal surface 111c of the third side 110c (also referred to as the ‘upper side’). As shown in FIG. 1B, the first and second wings 115a, 115b can be folded inwards and towards the cavity 105 such that the wings 115a, 115b lie folded in a horizontal plane above an electronic device accommodated within the underlying cavity 105. The cover 120 can be seen in unfolded or open position in FIG. 1B. Thereafter, as shown in FIG. 1A, the cover 120 can also be folded inwards and towards the folded wings 115a, 115b such that the cover 120 lies in a horizontal plane above the folded wings 115a, 115b.

In embodiments, the cavity 105 has a length ‘1’, a width ‘w’ and a depth ‘d’. In various embodiments, the length ‘1’ ranges from 4 inches to 24 inches and the width ‘w’ ranges from 4 inches to 24 inches to accommodate a wide variety and size of electronic devices. In some embodiments, the depth ‘d’ of the cavity 105 has a value such that it can accommodate the electronic device, the first and second wings 115a, 115b folded over the electronic device and the cover 120 folded over the first and second wings 115a, 115b while ensuring that the upper surface of the folded cover 120 is flush with the top edges of the first, second, third and (optional) fourth sides 110a, 110b, 110c and 110d. In some embodiments, the cover 120 when folded lies over the top edges of the first, second, third and (optional) fourth sides 110a, 110b, 110c and 110d. In various embodiments, the depth ‘d’ ranges from 0.5 inches to 5 inches.

As shown in FIG. 1B, when folded the first wing 115a has a first length l₁ and width ‘w’ while the second wing has a second length 12 and a width ‘w’ such that l₁+l₂<1 where ‘l’ is the length and ‘w’ is the width of the cavity 105. In some embodiments, l₁=l₂=½—that is, the first and second lengths of the respective first and second wings 115a, 115b are equal and half of the total length ‘l’ of the cavity 105. In some embodiments, the first and second lengths l₁, l₂ of the respective first and second wings 115a, 115b are equal however a sum of the first and second lengths is less than the length ‘l’ of the cavity 105. In some embodiments, the first and second lengths l₁, l₂ may be of unequal lengths however a sum of l₁ and l₂ is equal to ‘l’. In some embodiments, the first and second lengths l₁, l₂ may be of unequal lengths however a sum of the first and second lengths is less than the length ‘l’ of the cavity 105.

Referring now to FIGS. 1B, 1C and 1D, in order to open the holder 100 (from the closed configuration of FIG. 1A), the cover 120 is first unfolded outwards and away from the cavity 105—such that when fully unfolded, it lies in a plane that is either substantially perpendicular to the base 110e or makes an obtuse angle ‘θ_{c}’ with the base 110e. In some embodiments, the obtuse angle ‘θ_{c}’ ranges from 91 degrees to 120 degrees and every increment therein. Next, the first and second wings 115a, 115b are unfolded outwards and away from the cavity 105—such that when fully unfolded, each wing 115a, 115b lies in a plane that is either substantially perpendicular to the base 110e or makes an obtuse angle ‘θ_{w}’ with the base 110e. In some embodiments, the obtuse angle ‘θ_{w}’ ranges from 91 degrees to 140 degrees, and every increment therein.

It should be appreciated the wings 115a, 115b and top cover 120 are preferably made of rigid, opaque material, such as PVC, other plastics, wood or metal. More preferably, the rigid opaque material comprises 1) signal-blocking or EMF blocking material, such as mylar, cooper, aluminum or other metals, 2) sound absorbing material, such as cloth, foam, or other acoustic insulators, or 3) combinations thereof.

As shown in FIGS. 1C and 1D, the first and second wings 115a, 115b and the cover 120 in their fully unfolded configurations preferably prevent acoustic signals or EMF radiation, emanating from the electronic device held or positioned within the cavity 105, from scattering in the left direction beyond the unfolded first wing 115a, in the right direction beyond the unfolded second wing 115b and in the forward or distal direction beyond the unfolded cover 120.

With reference to FIG. 1C, it should be appreciated, that in embodiments where the cavity 105 is defined by the first, second, third and fourth sides 110a, 110b, 110c and 110d and the base 110e, the electronic device can be eased down vertically into the cavity 105 or lifted up vertically from the cavity 105. With reference to FIG. 1D, in embodiments where the cavity 105 is defined by the first, second, and third sides 110a, 110b, 110c and the base 110e, the electronic device can be slid-in from the now open fourth side 110d′ and into the cavity 105 or slid-out from the cavity 105.

In some embodiments, each of the first and second wings 115a, 115b comprises a single panel (FIGS. 1C, 1D). However, in some embodiments, each of the first and second wings 115a, 115b comprises at least two panels hinged to each other to allow for more flexible folding and unfolding movement of the wings. In one embodiment, as shown in FIG. 1B, the first wing 115a comprises a first panel 116a and a second panel 117a that are hinged to each other while the second wing 115b also comprises a first panel 116b and a second panel 117b that are hinged to each other, where each of the individual panels ranges from one-half to two thirds of the entire length of the wing.

### Second Embodiment

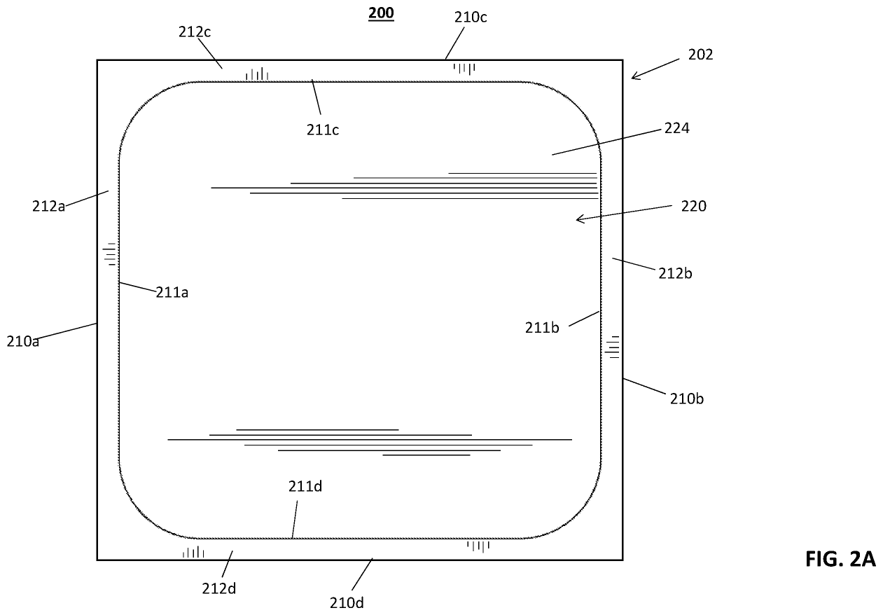

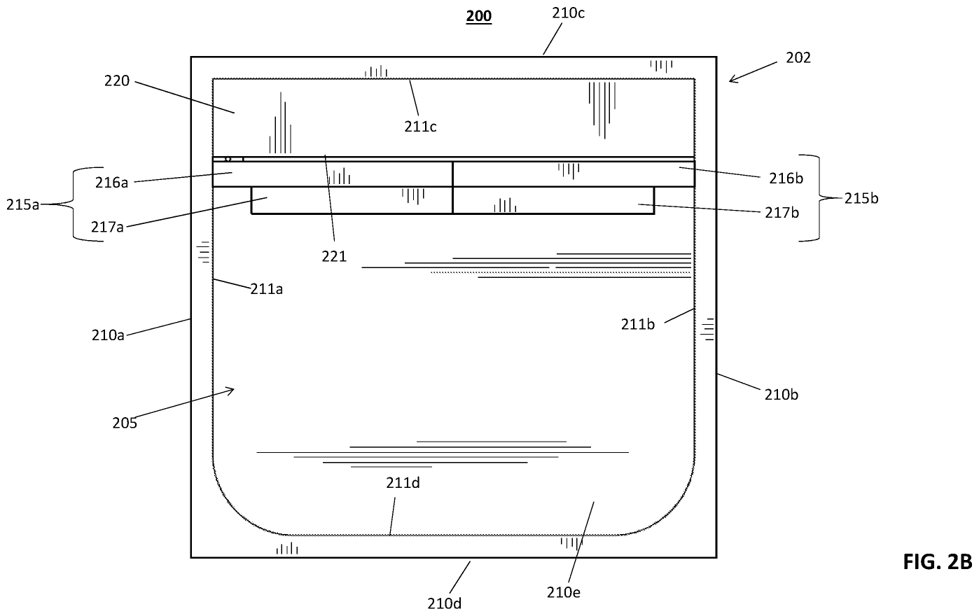

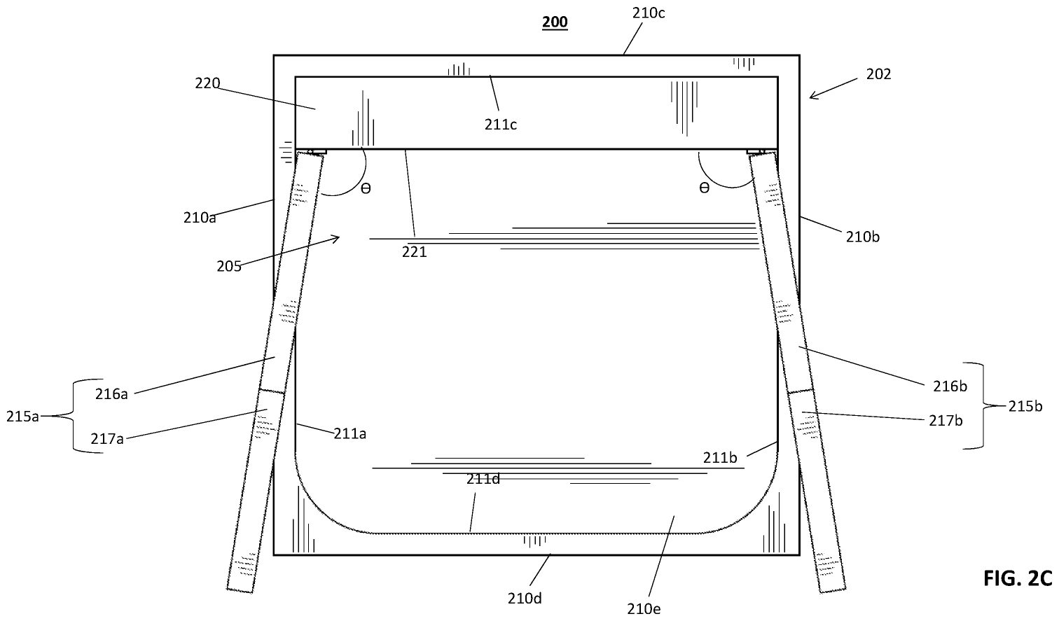

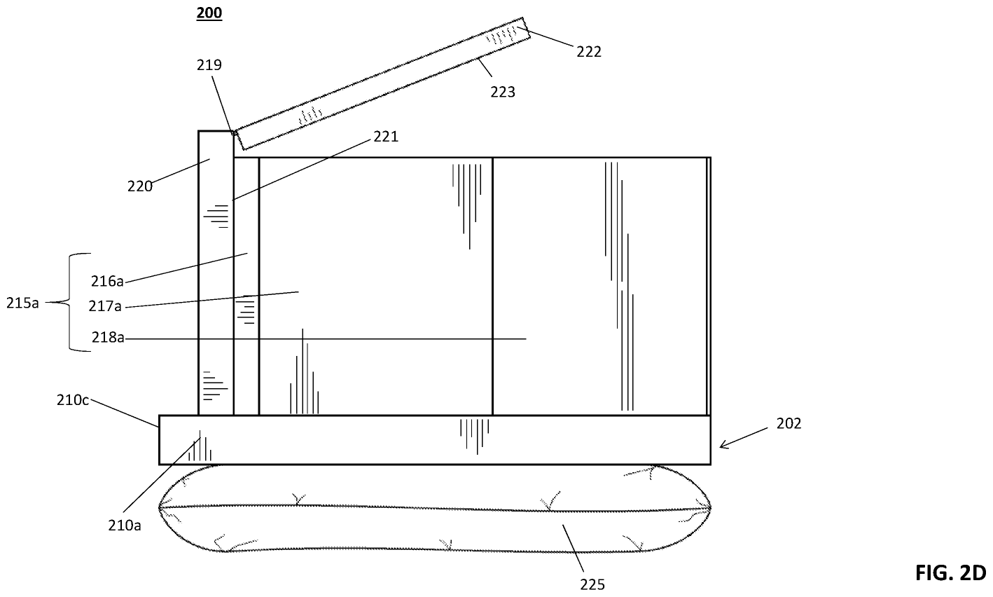

FIG. 2A shows a top view of an electronic device holder 200 in a closed configuration, FIG. 2B shows a top view of the electronic device holder 200 in a partially opened configuration, FIG. 2C shows a top view of the electronic device holder 200 in a fully opened configuration while FIG. 2D shows a side view of the electronic device holder 200 in a fully opened configuration, in accordance with some embodiments of the present specification. Referring now to FIGS. 2A, 2B, 2C and 2D simultaneously, the holder 200 comprises a casing 202 that incorporates therewithin a cavity 205 defined by first, second, third and fourth sides 210a, 210b, 210c and 210d and a base 210e. In various embodiments, the holder 200 is configured to be conveniently positioned on a user's lap. In various embodiments, the holder 200 is positioned over and/or removably embedded into a support 225 of soft and pliable material that acts as a cushion between the holder 200 and the user's lap.

In embodiments, in the closed configuration of FIG. 2A, the casing 202 acts as a desk-like structure that has a substantially quadrilateral shape such as, for example, rectangular, square, rhombus or parallelogram. In some embodiments, corners of the cavity 205 are rounded. In some embodiments, corners of the casing 202 are rounded. It should be appreciated that the length and width of the electronic device holder 200 is preferably sized to allow for being comfortably positioned on a user's lap. Accordingly, the length and width of the electronic device holder 200 is preferably less than 24 inches long and less than 24 inches wide.

When the holder 200 is positioned on a horizontal plane, the first and second sides 210a, 210b form left and right vertical sides, the third and fourth sides 210c, 210d form upper and lower horizontal sides while the base 210e forms a bottom surface lying in the horizontal plane. The first, second, third and fourth sides 210a, 210b, 210c and 210d respectively have internal surfaces (facing inwards into the cavity 205) 211a, 211b, 211c and 211d.

To use the device 200, the top cover 220 is first lifted up by holding a portion of the cover proximate the fourth side 210d, typically through a groove or small protrusion. Preferably, in a closed position, the top cover 220 is flush with one or more of the sides 210a, 210b, 210c, and 210d. The top cover 220 is hinged, connected, or otherwise rotatably attached to the third side 210c. Upon lifting the top cover 220, the edge of the top cover 220 proximate the fourth side 210d lifts vertically and is positioned above the device 200 such that the top cover 220 is now substantially perpendicular to the base 210e or cavity 205. FIG. 2B shows the top cover 220 lifted vertically and exposing components, such as a first wing 215a and a second wing 215b, positioned below the top cover 220 and inside the cavity 205. The first wing 215a and second wing 215b are attached to the top cover 220 and are in a folded configuration when the top cover 220 is first opened.

An edge of a cover 220 (the edge lying proximate the third side 210c) is hinged to the internal surface 211c of the third side 210c (also referred to as the ‘upper side’) such that the cover 220 can be folded downwards and towards the cavity 205 from an unfolded position and can be unfolded upwards and away from the cavity 205 from a folded position. In the unfolded position, as shown in FIGS. 2B, 2C and 2D, a plane of the cover 220 lies substantially perpendicular to the base 210e. In the folded position, as shown in FIG. 2A, the plane of the cover 220 lies substantially parallel to the underlying base 210e. In some embodiments, in the folded position (FIG. 2A), a top surface 224 of the cover 220 is flush with the top surfaces 212a, 212b, 212c, 212d of the edges of the respective first, second, third and fourth sides 210a, 210b, 210c and 210d. In some embodiments, corners of the cover 220 are rounded to fit into reciprocating rounded corners of the cavity 205. In some embodiments, corners of the casing 202 are rounded.

In some embodiments, a distal edge of a first wing 215a (also referred to as a ‘left wing’) is hinged to a left portion of an internal surface 221 of the cover 220 while a distal edge of a second wing 215b (also referred to as a ‘right wing’) is hinged to a right portion of the internal surface 221 of the cover 220. In this embodiment, each of the first and second wings 215a, 215b comprises a single panel.

In some embodiments, each of the first and second wings 215a, 215b comprises at least two panels hinged to each other to allow for more flexible folding and unfolding movement of the wings. In one embodiment, as shown in FIG. 2B, the first wing 215a comprises a first panel 216a of length l₁ₐ and a second panel 217a of length l₂ₐ while the second wing 215b also comprises a first panel 216b of length l_{1b} and a second panel 217b of length l_{2b}. In some embodiments, l₁ₐ>l₂ₐ and l_{1b}>l_{2b}—that is, the first panels 216a, 216b (that are closer to the cover 220) are longer than their respective second panels 217a, 217b (that are farther from the cover 220). In some embodiments, l₁ₐ=l₂ₐ and l_{1b}=l_{2b}—that is, the first panels 216a, 216b have lengths equal to their respective second panels 217a, 217b. A distal edge of the first panel 216a is hinged to the left portion of the internal surface 221 of the cover 220. Similarly, a distal edge of the first panel 216b is hinged to the right portion of the internal surface 221 of the cover 220. A proximal edge of the first panel 216a is hinged to a distal edge of the second panel 217a thereby flexibly coupling the first and second panels 216a, 217a together. Similarly, a proximal edge of the first panel 216b is hinged to a distal edge of the second panel 217b thereby flexibly coupling the first and second panels 216b, 217b together.

As shown in FIG. 2B, the first wing 215a can be folded (from an unfolded position of FIG. 2C) towards the internal surface 221 of the cover 220 such that the first panel 216a folds-in to touch the internal surface 221 while the second panel 217a folds-in thereafter to touch the folded first panel 216a. Similarly, the second wing 215b can also be folded towards the internal surface 221 of the cover 220 such that the first panel 216b folds-in to touch the internal surface 221 while the second panel 217b folds-in thereafter to touch the folded first panel 216a.

As shown in FIG. 2C, the first wing 215a can be unfolded (from a folded position of FIG. 2B) away from the internal surface 221 of the cover 220 such that the second panel 217a unfolds first followed by unfolding of the first panel 216a hinged to the second panel 217a. Similarly, the second wing 215b can be unfolded (from the folded position of FIG. 2B) away from the internal surface 221 of the cover 220 such that the second panel 217b unfolds first followed by unfolding of the first panel 216b hinged to the second panel 217b. In some embodiments, when fully unfolded, the first and second wings 215a, 215b extend beyond the cavity 205 (to help better block EMF radiation emanating from an electronic device positioned within the cavity 205) and are angled relative to the unfolded cover 220 such that angles ‘θ’ between the internal surfaces of the respective wings 215a, 215b and the internal surface 221 of the cover 220 is greater than 90 degrees. This is advantageous if a user has his laptop housed within the cavity 205 and needs requisite width for his hands to access the keyboard.

In some embodiments, each of the first and second wings 215a, 215b comprises three panels hinged to each other to allow for more flexible folding and unfolding movement of the wings. In one embodiment, as shown in FIG. 2D, the first wing 215a comprises a first panel 216a of length l₁ₐ, a second panel 217a of length l₂ₐ and a third panel 218a of length l₃ₐ while the second wing 215b also comprises a first panel 216b of length l_{1b}, a second panel 217b of length l_{2b} and a third panel 218b of length l_{3b} (in FIG. 2D only the first wing 215a is visible). In some embodiments, for the first wing 215a, the first panel 216a is substantially shorter than the second and third panels 217a, 218a while the second and third panels 217a, 218a may or may not be of equal lengths. Similarly, for the second wing 215b, the first panel 216b is substantially shorter than the second and third panels 217b, 218b while the second and third panels 217b, 218b may or may not be of equal lengths. In some embodiments, the first panels 216a, 216b are of equal lengths, the second panels 217a, 217b are of equal lengths and the third panels 218a, 218b are also of equal lengths.

In the embodiment, a distal edge of the first panel 216a is hinged to the left portion of the internal surface 221 of the cover 220. Similarly, a distal edge of the first panel 216b is hinged to the right portion of the internal surface 221 of the cover 220. A proximal edge of the first panel 216a is hinged to a distal edge of the second panel 217a while a proximal edge of the second panel 217a is hinged to a distal edge of the third panel 218a thereby flexibly coupling the first, second and third panels 216a, 217a, 218a together. Similarly, a proximal edge of the first panel 216b is hinged to a distal edge of the second panel 217b while a proximal edge of the second panel 217b is hinged to a distal edge of the third panel 218b thereby flexibly coupling the first, second and third panels 216b, 217b, 218b together.

The first wing 215a can be folded (from an unfolded position of FIG. 2D) towards the internal surface 221 of the cover 220 such that the first panel 216a folds-in to touch the internal surface 221, the second panel 217a folds-in next to touch the folded first panel 216a while the third panel 218a folds-in thereafter to touch the folded second panel 217a. Similarly, the second wing 215b can also be folded towards the internal surface 221 of the cover 220 such that the first panel 216b folds-in to touch the internal surface 221, the second panel 217b folds-in next to touch the folded first panel 216b while the third panel 218b folds-in thereafter to touch the folded second panel 217b.

The first wing 215a can be unfolded (from a folded position) away from the internal surface 221 of the cover 220 such that the third panel 218a unfolds first followed by unfolding of the second panel 217a hinged to the third panel 218a and finally followed by unfolding of the first panel 216a hinged to the second panel 217a. Similarly, the second wing 215b can be unfolded (from a folded position) away from the internal surface 221 (shown in FIG. 2C) of the cover 220 such that the third panel 218b unfolds first followed by unfolding of the second panel 217b hinged to the third panel 218b and finally followed by unfolding of the first panel 216b hinged to the second panel 217b.

In some embodiments, as shown in FIG. 2D, an optional top wing 222, hinged to a proximal edge 219 of the cover 220, locks in an inclined position with reference to a vertical position of the unfolded cover 220 when pushed up. When folded, an internal surface 223 of the top wing 222 touches or abuts the internal surface 221 of the cover 220 after which the cover 220 is folded towards the cavity 205. In some embodiments, when the cover 220, top wing 222, first wing 215a and second wing 215b are in unfolded configuration netting or cloth portions extend between a left edge of the top wing 222 and the top edge of the first wing 215a as well as between a right edge of the top wing 222 and the top edge of the second wing 215b. It should be appreciated that the netting or cloth further block EMF radiations emanating from the electronic device positioned within the cavity 205.

It should be appreciated the wings 215a, 215b and top cover 220 are preferably made of rigid, opaque material, such as PVC, other plastics, wood or metal. More preferably, the rigid opaque material comprises 1) signal-blocking or EMF blocking material, such as mylar, cooper, aluminum or other metals, 2) sound absorbing material, such as cloth, foam, or other acoustic insulators, or 3) combinations thereof.

### Third Embodiment

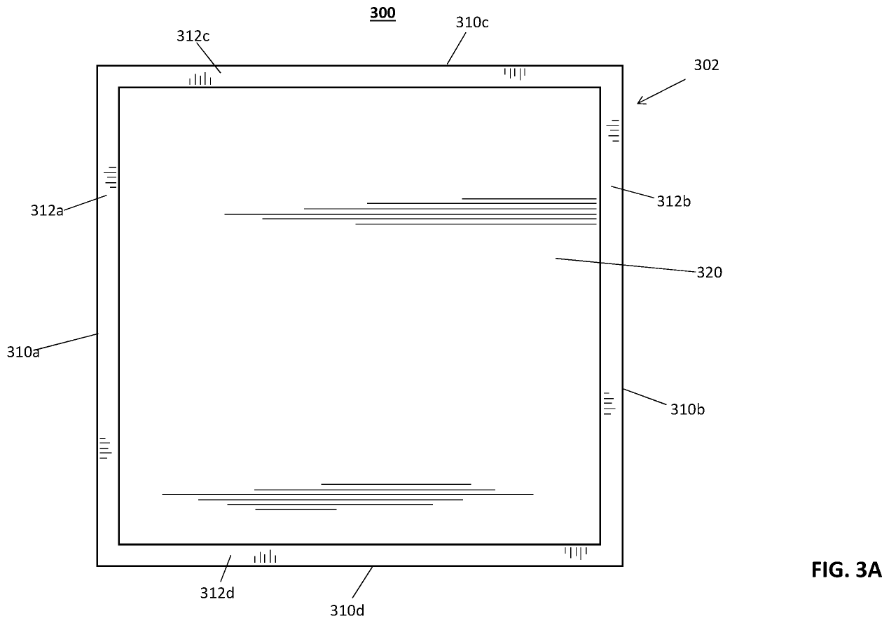

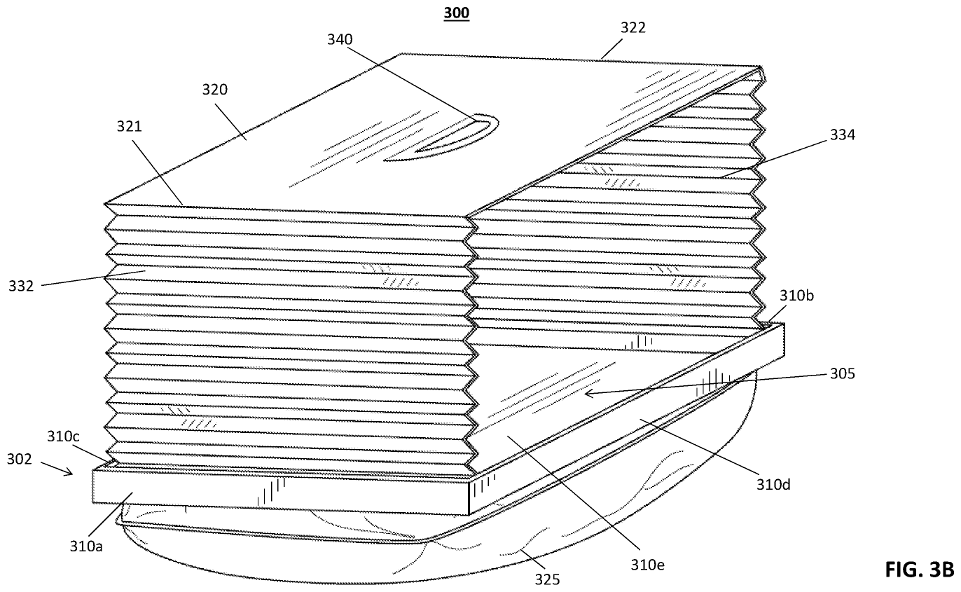

FIG. 3A shows a top view of an electronic device holder 300 in a closed configuration, while FIG. 3B shows a perspective view of the electronic device holder 300 in a fully opened configuration, in accordance with some embodiments of the present specification. Referring now to FIGS. 3A and 3B simultaneously, the holder 300 comprises a casing 302 that incorporates therewithin a cavity 305 defined by first, second, third and fourth sides 310a, 310b, 310c and 310d and a base 310e. In various embodiments, the holder 300 is configured to be conveniently positioned on a user's lap. In various embodiments, the holder 300 is positioned over and/or removably embedded into a support 325 of soft and pliable material that acts as a cushion between the holder 300 and the user's lap.

In embodiments, in the closed configuration of FIG. 3A, the casing 302 acts as a desk-like structure that has a substantially quadrilateral shape such as, for example, rectangular, square, rhombus or parallelogram. In some embodiments, corners of the cavity 305 are rounded. In some embodiments, corners of the casing 302 are rounded.

When the holder 300 is positioned on a horizontal plane, the first and second sides 310a, 310b form left and right vertical sides, the third and fourth sides 310c, 310d form upper and lower horizontal sides while the base 310e forms a bottom surface lying in the horizontal plane.

A first wall 332 couples or attaches a first side 321 of a cover 320 to an internal surface (facing inwards into the cavity 305) of the first side 310a of the casing 302. A second wall 334 couples or attaches a second side 322 of the cover 320 to an internal surface (facing inwards into the cavity 305) of the second side 310b of the casing 302. In some embodiments, the first and second walls 332, 334 comprise layered accordion-like structures that expand when an upward force is applied by pulling the cover 320 (away from the cavity 305) using an optional handle 340 and collapse when a downward force is applied by pushing the cover 320 towards the cavity 305 using the handle 340.

When the cover 320 is closed, as shown in FIG. 3A, a top surface of the cover 320 is flush with the top surfaces 312a, 312b, 312c, 312d of the edges of the respective first, second, third and fourth sides 310a, 310b, 310c and 310d. When the cover 320 is open, as shown in FIG. 3B, the accordion structured walls 332, 334 stay locked or held-up in expanded configuration and do not collapse on their own unless a deliberate downward force is applied to the cover 320. In expanded configuration, the accordion structured walls 332, 334 prevent EMF radiations, from an electronic device housed within the cavity 305, from scattering beyond the first and second walls 332, 334. In some embodiments, corners of the cover 320 are rounded to fit into reciprocating rounded corners of the cavity 305.

Each of the electronic device holders, in accordance with various embodiments of the present specification, are fabricated from one or more layers of materials that offer a combination of durability, light weight and EMF radiation blocking and/or absorption while at the same time being non-toxic. In some embodiments, the holders are fabricated from any one or a combination of materials such as, but not limited to, mylar, plastic, PVC, wood, stainless steel, aluminum. In some embodiments, the holders may be made of wood, stainless steel or aluminum and may further comprise an external fabric cover sized to fit the holders, wherein the fabric material may be a multi-metallized fabric made with polyester, nickel and copper. Alternatively, the fabric material may be of stainless steel wire knitted with polyester yarn or thin silver coated copper wires spun with cotton or polyester yarns, for example. These fabrics aid in reducing EMF emanating from electronic devices positioned within the holders of the present specification.

The above examples are merely illustrative of the many applications of the system and method of present specification. Although only a few embodiments of the present specification have been described herein, it should be understood that the present specification might be embodied in many other specific forms without departing from the spirit or scope of the specification. Therefore, the present examples and embodiments are to be considered as illustrative and not restrictive, and the specification may be modified within the scope of the appended claims.

We claim:

1. An electronic device holder dimensioned to be positioned on a lap of a user comprising:
a casing incorporating a cavity configured to accommodate an electronic device, wherein the cavity is defined by a first wall, a second wall, a third wall, a fourth wall and a base and wherein each of the first wall, the second wall, the third wall and the fourth wall have an internal surface facing the cavity; and
a cover rotatably attached to the internal surface of the third wall, wherein the cover is configured to be folded downwards and towards the cavity from an unfolded position and configured to be unfolded upwards and away from the cavity from a folded position.

2. The electronic device holder of claim 1 further comprising:
a first wing having a distal edge hinged to a left portion of an internal surface of the cover, wherein, in the folded position, the first wing is positioned under the cover and within the cavity.

3. The electronic device holder of claim 2 further comprising:
a second wing having a distal edge hinged to a right portion of the internal surface of the cover, wherein, in the folded position, the second wing is positioned under the cover and within the cavity.

4. The electronic device holder of claim 1, wherein, in the unfolded position, a plane of the cover lies substantially perpendicular to the base whereas in the folded position the plane of the cover lies substantially parallel to the base.

5. The electronic device holder of claim 2, wherein, in the unfolded position, an internal surface of the first wing is positioned at an angle relative to the internal surface of the cover and wherein the angle is greater than 90 degrees.

6. The electronic device holder of claim 3, wherein, in the unfolded position, an internal surface of the second wing is positioned at a second angle relative to the internal surface of the cover and wherein the second angle is greater than 90 degrees.

7. The electronic device holder of claim 1, wherein, in the folded position, an external surface of the cover is flush with a top surface of each of the first wall, the second wall, the third wall and the fourth wall.

8. The electronic device holder of claim 1, wherein the casing has a substantially quadrilateral shape and wherein corners of the casing are rounded.

9. The electronic device holder of claim 2, wherein the first wing comprises a first panel and a second panel and wherein the first panel and the second panel are rotatably connected to each other.

10. The electronic device holder of claim 9, wherein the first panel is longer than the second panel of the first wing.

11. The electronic device holder of claim 9, wherein the first wing is configured to be folded towards an internal surface of the cover such that the first panel of the first wing folds-in to touch the internal surface of the cover while the second panel of the first wing folds-in thereafter to touch the folded first panel

12. The electronic device holder of claim 11, wherein the first wing is configured to be unfolded away from the internal surface of the cover such that the second panel of the first wing unfolds followed by an unfolding of the first panel of the first wing.

13. The electronic device holder of claim 3, wherein the second wing comprises a first panel and a second panel and wherein the first panel of the second wing and the second panel of the second wing are rotatably connected to each other.

14. The electronic device holder of claim 13, wherein the first panel of the second wing is longer than the second panel of the second wing.

15. The electronic device holder of claim 13, wherein the second wing is configured to be folded towards the internal surface of the cover such that the first panel of the second wing folds-in to touch the internal surface of the cover while the second panel of the second wing folds-in thereafter to touch the folded first panel of the second wing.

16. The electronic device holder of claim 13, wherein the second wing is configured to be unfolded away from the internal surface of the cover such that the second panel of the second wing unfolds followed by an unfolding of the first panel of the second wing.

17. The electronic device holder of claim 3, wherein the first wing and the second wing are hinged to proximal edges of the cover, wherein the first wing and the second wing are configured to lock at an angle relative to the internal surface of the cover when said cover is in the unfolded position, and wherein the angle is greater than 90 degrees.

18. The electronic device holder of claim 1, further comprising a cushion, wherein a bottom surface of the casing is attached to the cushion.
